(19) United States
(12) Patent Application Publication
(10) Pub. No.: US 2011/0222228 A1
(43) Pub. Date: Sep. 15, 2011

(54) ELECTRONIC CARD CONTAINING A DISPLAY WINDOW AND METHOD FOR MANUFACTURING AN ELECTRONIC CARD CONTAINING A DISPLAY WINDOW

(75) Inventor: Robert SINGLETON, Lakeland, FL (US)

(73) Assignee: Innovatier, Inc.

(21) Appl. No.: 13/047,236

(22) Filed: Mar. 14, 2011

Related U.S. Application Data
(60) Provisional application No. 61/282,677, filed on Mar. 15, 2010.

(51) Int. Cl. G06F 1/16; B32B 37/02; B32B 37/14; H05K 3/00; H05K 3/22; H05K 3/30; B32B 38/10; H05K 7/00

(52) U.S. Cl. 361/679.4; 156/256; 156/245; 216/20; 361/760

(57) ABSTRACT

One embodiment of the invention relates to an electronic card containing a clear display window. The electronic card includes a printed circuit board, having a top surface and a bottom surface and a plurality of circuit components including a display disposed on the top surface of the printed circuit board. The electronic card further includes a bottom overlay disposed on the bottom surface of the printed circuit board, a top overlay disposed above the top surface of the printed circuit board, and a core layer positioned between the top surface of the bottom overlay and the bottom surface of the top overlay. The top overlay comprises a display window aligned with the display.

### CROSS-REFERENCE TO RELATED PATENT APPLICATIONS

This application claims priority from U.S. Provisional Application Ser. No. 61/282,677, filed Mar. 15, 2010.

### BACKGROUND

The present invention relates generally to the field of smart cards. Smart cards or integrated circuit cards are pocket-sized cards (e.g., credit cards, gift cards, identification cards, etc.) that includes an embedded integrated circuit. Such cards may be used for a wide range of applications, including identification, data storage, and authentication.

### SUMMARY

One embodiment of the invention relates to an electronic card containing a clear display window. The electronic card includes a printed circuit board, having a top surface and a bottom surface and a plurality of circuit components including a display disposed on the top surface of the printed circuit board. The electronic card further includes a bottom overlay disposed on the bottom surface of the printed circuit board, a top overlay disposed above the top surface of the printed circuit board, and a core layer positioned between the top surface of the bottom overlay and the bottom surface of the top overlay. The top overlay comprises a display window aligned with the display.

Another embodiment relates to a method for manufacturing an overlay for an electronic card. The method includes providing an opaque web material, rotary die cutting a predetermined window configuration in the web material, and laminating a clear material to the web material.

Still another embodiment relates to a method for manufacturing an embedded electronic device. The method includes providing a printed circuit board having a top surface and a bottom surface, the bottom surface includes a plurality of standoffs. The method further includes affixing a plurality of circuit components onto the top surface of the printed circuit board and affixing the bottom surface of the printed circuit board to a bottom overlay using a pressure sensitive adhesive tape or a spray-on adhesive. The method further includes loading the printed circuit board and bottom overlay into an injection molding apparatus and loading a top overlay positioned above a top surface of the printed circuit board into the injection molding apparatus. The method further includes injecting thermosetting polymeric material between the top surface of the printed circuit board, the plurality of circuit components and the top overlay; and injecting thermosetting polymeric material between the bottom surface of the printed circuit board and the bottom overlay.

It is to be understood that both the foregoing general description and the following detailed description are exemplary and explanatory only, and are not restrictive of the invention as claimed.

### BRIEF DESCRIPTION OF THE DRAWINGS

These and other features, aspects and advantages of the present invention will become apparent from the following description, appended claims, and the accompanying exemplary embodiments shown in the drawings, which are briefly described below.

FIG. 1 is a view of mechanism for forming a laminated web material is shown according to one exemplary embodiment.

FIG. 2 is a top view of a cut web material showing clear display windows according to one exemplary embodiment.

FIG. 3 is a sectional view of the web material of FIG. 2 according to one exemplary embodiment.

FIG. 4 is a flowchart of a method of manufacturing a top overlay for an integrated circuit card according to an exemplary embodiment.

FIG. 5 is a flowchart of a method of manufacturing an integrated circuit card according to an exemplary embodiment.

### DETAILED DESCRIPTION

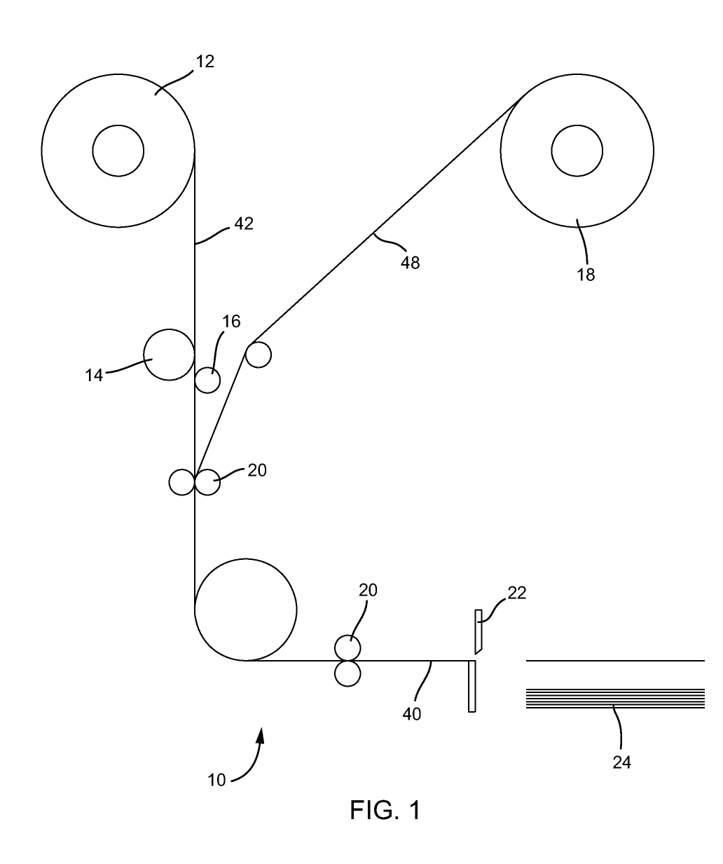

Referring to FIG. 1, a mechanism 10 for forming a laminated overlay 40 for a card 30 (e.g., a smart card, integrated circuit card (ICC), etc.). The laminated overlay 40 comprises an opaque web material 42 and a clear overlay material 48. The opaque web material 42 may have a printed surface or may be unprinted. According to one exemplary embodiment, the opaque web material 42 is polyvinyl chloride (PVC). According to other exemplary embodiments, the opaque web material 42 may be acrylonitrile butadiene styrene (ABS), or any other suitable polymer or other material.

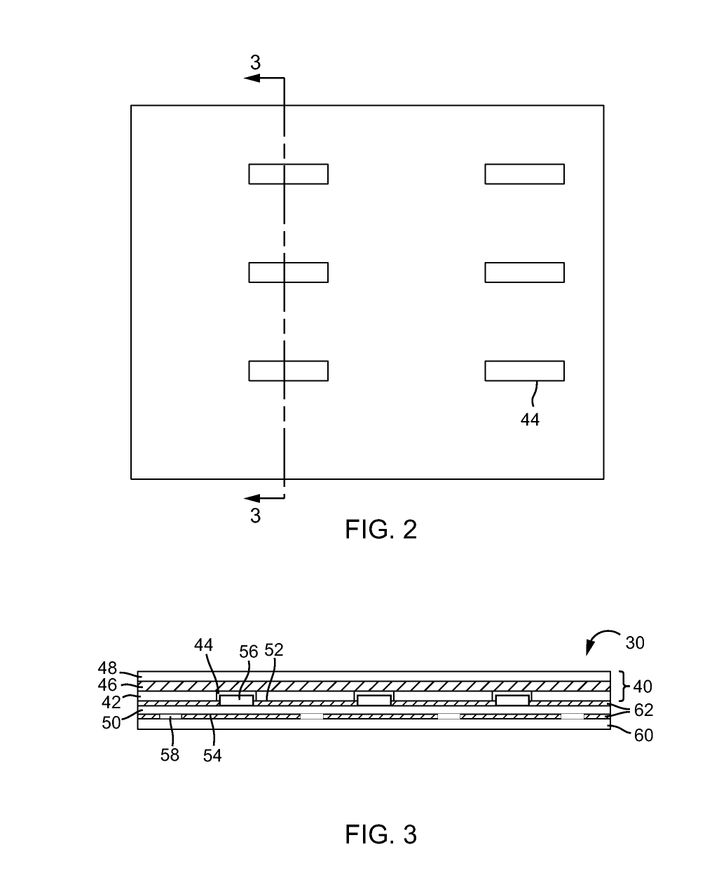

The opaque web material 42 is fed into the mechanism 10 from a first input or feed roll 12. The opaque web material 42 is fed into a rotary die 14 where a cuts an opening 44 of a predetermined size and shape (see FIG. 2) is cut in the opaque web 42. The opening 44 forms a window in the opaque web material 42 to allow device or feature in the card disposed below the opaque web material 42 to be viewed.

After being cut, a laminate adhesive 46 (see FIG. 3) is applied to the surface of the web material 42 with an application device 16. The laminate adhesive 46 is a transparent adhesive so it does not obscure or mask the opaque web material 42. The adhesive may be any type of suitable adhesive, such as a pressure-sensitive adhesive, a heat-activated adhesive, a chemically-activated adhesive, etc. The adhesive may be a variety of forms, such as a tape, a film, or as a sprayed liquid.

A clear or transparent overlay material 48 is fed into the mechanism 10 from a second input or feed roll 18. The clear overlay material 48 is coupled to the opaque web material 42 with the adhesive 46. The stacked layers may pass through one or more devices such as paired rollers 20 to further adhere the clear overlay material 48 to the opaque web material 42 and form a laminated overlay 40.

The laminated overlay 40 can then be sheet cut with a cutting device 22 into discreet segments or sheets 24. The sheets 24 may then be stacked and stored or transported for later processing. With reference to FIGS. 2 and 3, a card 30 containing a clear display window 44 is shown according to an exemplary embodiment. The card 30 includes a top overlay 40, a printed circuit board 50, a bottom overlay 60, and a core layer 62 formed from a thermosetting polymeric material.

The printed circuit board 50 has a top surface 52 and a bottom surface 54. According to an exemplary embodiment, the printed circuit 50 is formed of a flame retardant laminate with woven glass reinforced epoxy resin (FR-4). However, the printed circuit 50 may be any other suitable dielectric material. One or more circuit components 56 are disposed on the top surface 52 of the printed circuit board 50. According to an exemplary embodiment, the circuit component is a display. In other embodiments, a wide variety of circuit components 56 may be disposed on the top surface 52 including, but not limited to a push button, a battery, a microprocessor chip, or a speaker. Circuit components 56 may also be disposed on the bottom surface 54. The bottom surface 54 of the printed circuit board 50 may further include standoffs 58 or other non-circuit components (e.g., supports, spacers, etc.).

The top surface 52 of the printed circuit board 50 further includes a plurality of circuit traces configured to operably connect to the circuit components 56. The bottom surface 54 may also include a plurality of circuit traces on the bottom surface configured to operably connect the circuit components 56 on the bottom surface 54 of the printed circuit board 50. The circuit traces may be formed with conductive ink. The circuit traces may be etched onto the printed circuit board 50. According to one exemplary embodiment, a plurality of embedded electronic devices 56 are formed on one printed circuit board 50. According to other exemplary embodiments, the card 30 may include multiple printed circuit boards 50.

A top overlay 40 and a bottom overlay 60 are coupled to the top surface 52 and the bottom surface 54 of the printed circuit board 50, respectively. The top overlay 40 and the bottom overlay 60 may be formed, at least partially, from a thermoplastic material such as polyvinyl chloride (PVC). According to an exemplary embodiment, the top overlay 40 includes an opaque web material 42 that is coupled to a clear overlay layer 48 with an adhesive 46. The adhesive layer 46 may be applied across the entire surface of the transparent overlay material 48, as shown in FIG. 3, or may be applied to the opaque web material 42 and therefore be absent from the openings 44. The top overlay 40 includes windows 44 that are aligned with circuit components 56 and allow one or more circuit components 56 (such as a display) to be viewed through the top overlay 40.

A core layer 62 is positioned between the top surface of the bottom overlay 60 and the bottom surface of the top overlay 40 (e.g., around the printed circuit board 50). The core layer 62 is approximately the same thickness as the printed circuit board 50 such that the finished card 30 has a generally constant thickness. According to an exemplary embodiment, the core layer 62 is comprised of thermosetting polyurea that is injected around the printed circuit board 50 into the space between the top overlay 40 and the bottom overlay 60.

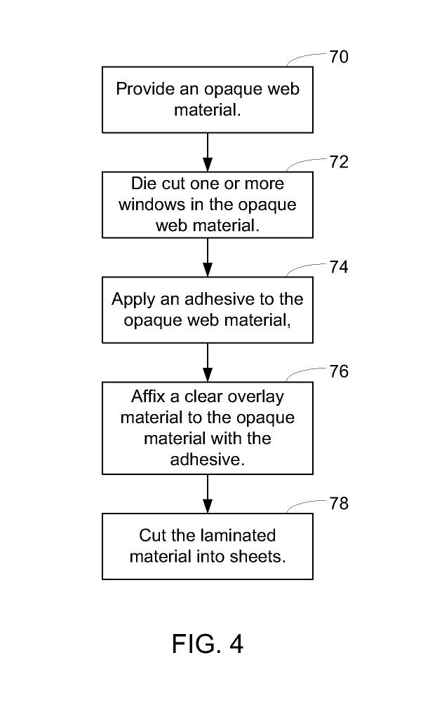

Referring now to FIG. 4, a flowchart of a method for forming a top overlay 40 (as shown in FIGS. 2 and 3) with the mechanism shown in FIG. 1. In a first step 70, an opaque web material 42 is provided (e.g., on a feed roll 12). In a second step 72, one or more openings or windows 44 are die cut in the opaque web material 42 (e.g., with a rotary die 14). In a third step 74, an adhesive 46 is applied to the opaque web material 42 and/or the clear overlay material 48. In a fourth step 76, the clear overlay layer 48 is affixed to the opaque web layer 42 with the adhesive 46. The adhesive 46 may be activated in a variety of ways (e.g., pressure, heat, chemicals, etc.) to form a laminated top overlay 40. In a fifth step 78, the laminated material is cut into a series of discreet sheets 24.

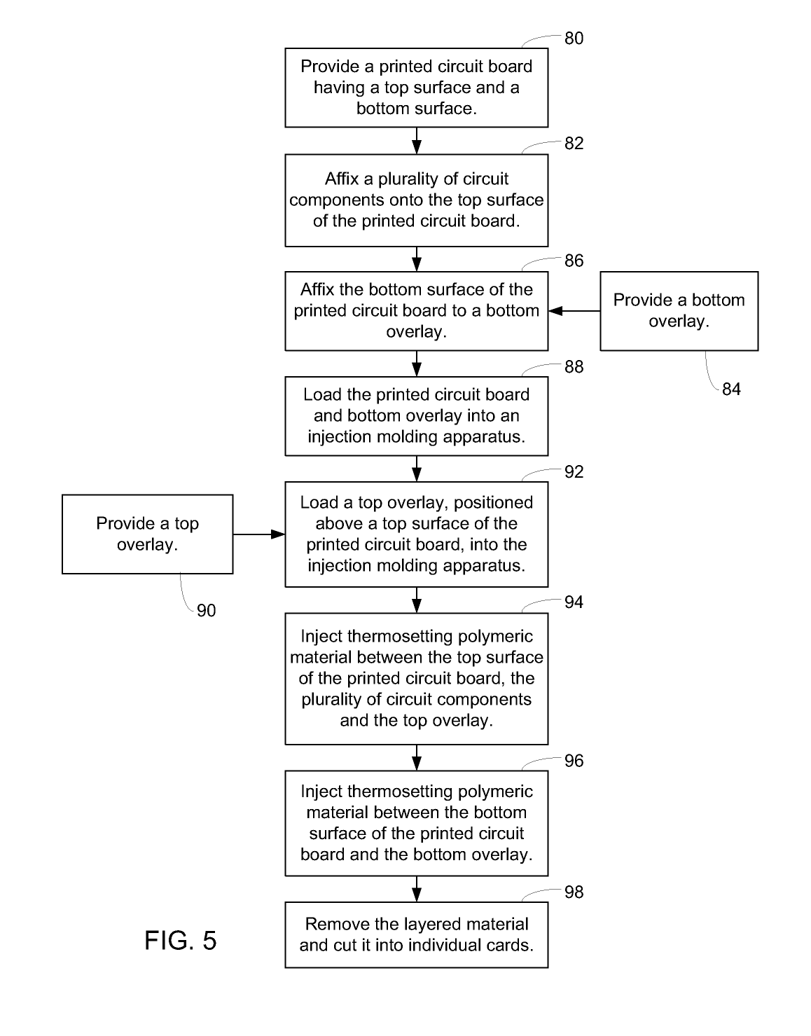

Referring now to FIG. 5, a flowchart of a method for forming an integrated circuit card 30 is shown according to an exemplary embodiment. In a first step 80, a printed circuit board 50 having a top surface 52 and a bottom surface 54 is provided. In a second step 82, a plurality of circuit components 56 are affixed onto the top surface 52 of the printed circuit board 50. In a third step 84, a bottom overlay 60 is provided. In a fourth step 86, the bottom surface 54 of the printed circuit board 50 is affixed to the bottom overlay 60. In a fifth step 58, the printed circuit board 50 and the bottom overlay 60 are loaded into an injection molding apparatus. In a sixth step 90, a top overlay 40 is provided. Top overlay 40 may be manufactured using an apparatus as shown in FIG. 1 and according to a method as shown in FIG. 4. In a seventh step 92, the top overlay 40 is loaded into the injection molding apparatus such that it is positioned above the top surface 52 of the printed circuit board 50. The top overlay 40 is positioned such that a window 44 in the top overlay 40 is aligned with a printed circuit board 50. In an eighth step 94, a thermosetting polymeric material 62 is injected between the top surface 52 of the printed circuit board, the plurality of circuit components 56, and the top overlay 40. In a ninth step 96, thermosetting polymeric material 62 is injected between the bottom surface 54 of the printed circuit board 50 and the bottom overlay 60. According to an exemplary embodiment, the top overlay 40 and the bottom overlay 60 are provided in the injection molding apparatus as sheets that each comprise a multitude of cards. In a tenth step 98, the laminated body comprising the top overlay 40, the printed circuit board 50, the bottom overlay 60, and the core material 62 is removed from the injection molding apparatus and cut into individual cards 30.

What is claimed is:

1. A method for manufacturing an overlay for an electronic card comprising:
providing an opaque web material,
rotary die cutting a predetermined window configuration in the web material, and
laminating a clear material to the web material.

2. An electronic card containing a clear display window comprising:
a printed circuit board, having a top surface and a bottom surface,
a plurality of circuit components including a display disposed on the top surface of the printed circuit board;
a bottom overlay disposed on the bottom surface of the printed circuit board;
a top overlay disposed above the top surface of the printed circuit board, and
a core layer positioned between the top surface of the bottom overlay and the bottom surface of the top overlay, wherein
the top overlay comprises a display window aligned with the display.

3. The electronic card of claim 2, wherein the printed circuit board comprises a plurality of circuit traces on the top surface configured to operably connect to the plurality of circuit components and may have a plurality of circuit traces on the bottom surface configured to operably connect to a plurality of circuit components on the bottom surface of the printed circuit board.

4. The electronic card of claim 2, wherein the plurality of circuit traces are formed with conductive ink.

5. The electronic card of claim 2, wherein the plurality of circuit traces are etched onto the printed circuit board.

6. The electronic card of claim 2, wherein the printed circuit board comprises a flame retardant laminate with woven glass reinforced epoxy resin (FR-4).

7. The electronic card of claim 2, wherein the top overlay and the bottom overlay are polyvinyl chloride.

8. The electronic card of claim 2, wherein the core layer is comprised of thermosetting polyurea.

9. The electronic card of claim 2, wherein one of the plurality of circuit components includes at least one push button.

10. The electronic card of claim 2, wherein one of the plurality of circuit components includes at least one battery.

11. The electronic card of claim 2, wherein one of the plurality of circuit components includes at least one microprocessor chip.

12. The electronic card of claim 2, wherein one of the plurality of circuit components includes at least one speaker.

13. The electronic card of claim 2, wherein one of the plurality of circuit components includes at least one display.

14. A method for manufacturing an embedded electronic device, comprising:
providing a printed circuit board having a top surface and a bottom surface, wherein the bottom surface includes a plurality of standoffs;
affixing a plurality of circuit components onto the top surface of the printed circuit board;
affixing the bottom surface of the printed circuit board to a bottom overlay using a pressure sensitive adhesive tape or a spray-on adhesive;
loading the printed circuit board and bottom overlay into an injection molding apparatus;
loading a top overlay positioned above atop surface of the printed circuit board into the injection molding apparatus;
injecting thermosetting polymeric material between the top surface of the printed circuit board, the plurality of circuit components and the top overlay; and
injecting thermosetting polymeric material between the bottom surface of the printed circuit board and the bottom overlay.

15. The method of claim 14, wherein the thermosetting polymeric material is polyurea.

16. The method of claim 14, wherein a plurality of embedded electronic devices are formed on one printed circuit board.

17. The method of claim 14, further comprising removing the injected top and bottom overlay from the mould; and cutting out the plurality embedded electronic devices.

18. The method of claim 14, wherein the circuit traces are formed by etching traces into the printed circuit board.
